(19) United States
(12) Patent Application Publication
(10) Pub. No.: US 2006/0033138 A1
(43) Pub. Date: Feb. 16, 2006

(54) Method for manufacturing semiconductor device, and semiconductor device

(76) Inventor: Shinichi Fukada, Tokyo-to (JP)

Correspondence Address: EPSON RESEARCH AND DEVELOPMENT INC;INTELLECTUAL PROPERTY DEPT, 150 RIVER OAKS PARKWAY, SUITE 225, SAN JOSE, CA, 95134, US

(21) Appl. No.: 11/200,676

(22) Filed: Aug. 10, 2005

(30) Foreign Application Priority Data
Aug. 12, 2004 (JP) 2004-235230

(51) Int. Cl. H01L 29/76

(52) U.S. Cl. 257/296

(57) ABSTRACT

A manufacturing method for a semiconductor device that has a first region for memory elements and a second region for elements other than memory elements on a substrate, includes forming a first interlayer dielectric film on the substrate. A first opening section, which is made to reach the substrate, is formed in the first interlayer dielectric film over the first region. A second opening section, which also reaches the substrate, is formed in the first interlayer dielectric film over the second region. A first plug electrode is formed in the first opening section and a second plug electrode is formed in the second opening section. A ferroelectric capacitor is formed on the first interlayer dielectric film and made to cover and contact the first plug electrode. A first wiring pattern covering and contacting the second plug electrode is formed on the first interlayer dielectric film. A second interlayer dielectric film, which covers the ferroelectric capacitor and the first wiring pattern, is formed on the first interlayer dielectric film. A third opening section is then made in the second interlayer dielectric film over the second region and reaching the first wiring pattern. A third plug electrode is formed in the third opening section.

### RELATED APPLICATIONS

Japanese application No. 2004-235230 is hereby incorporated by reference in its entirety.

### BACKGROUND OF THE INVENTION

1. Field of the Invention

The present invention relates to methods for manufacturing semiconductor devices and to semiconductor devices, and more particularly relates to a method for manufacturing an embedded FeRAM in which a ferroelectric capacitor and a logic circuit are mix-mounted (i.e. constructed on the same integrated circuit, IC), and a method for manufacturing the same.

2. Description of the Related Art

Conventionally, ferroelectric memories (FeRAMs: ferroelectric memories) have been widely known as nonvolatile memories using polarization hysteresis characteristics of ferroelectric materials. Because FeRAMs are capable of operating with low power consumption and at high speed, demand for FeRAMs is growing. Miniaturization and higher-integration of such FeRAMs are advancing like other memory devices such as DRAMs (dynamic random access memories). For example, Japanese Laid-open Patent Application 2000-36568 describes a planar type FeRAM. However, a stacked type FeRAM would be preferred over a planar type FeRAM in view of the need for further miniaturization and higher-integration. Consequently, stacked type FeRAMs have been rapidly gaining in popularity in recent years.

FeRAMs have already been commercialized, and their basic structure has been publicly known for some time. However, they are mainly used as embedded memories for microcomputers in which logic circuits are mix-mounted, and not as single purpose memory devices, which were expected at the beginning. Therefore an effective unification of the FeRAM manufacturing process with the manufacturing process of logic circuits has become very important, but the process itself has rarely been reviewed from such a point of view as described above. This is because only a few years have passed since FeRAMs' main use as memories for mix-mounted applications has became clear, and therefore what would be new objectives for FeRAMs when viewed with this use in mind have not been sufficiently defined.

FIG. 7 is a cross-sectional view showing a conventional structure of a semiconductor device 300. As shown in FIG. 7, semiconductor device 300 is an embedded memory, and has a memory region and a logic circuit region in a semiconductor substrate 301. A cell selection MOS transistor (i.e. select transistor) 310 and a ferroelectric capacitor 330 are formed in the memory region of the semiconductor substrate 301. An MOS transistor 315 that is used for a purpose other than cell selection is formed in the logic circuit region of the semiconductor substrate 301. Then, the cell selection MOS transistor 310 and the MOS transistor 315 are covered by a first interlayer dielectric film 320.

As shown in FIG. 7, one of a source region or a drain region (hereafter, S/D regions) of the cell selection MOS transistor 310 is connected to a lower electrode film 331 of the ferroelectric capacitor 330 through a tungsten via, or plug electrode, (hereafter referred to as a “plug electrode”) 321. Also, the other of the S/D regions 311 of the cell selection MOS transistor 310 and S/D regions 316 of MOS transistor 315 in the logic circuit region are lead out to the surface of a second interlayer dielectric film 370 by two stacked (i.e. laminated) plug electrodes 321 and 341.

It has been considered essential for an ordinary FeRAM in a 2T2C/1T1C structure (i.e. a 2 Transistor, 2 Capacitor structure or a 1 Transistor, 1 Capacitor structure, respectively), such as the semiconductor device 300 of the conventional FeRAM shown in FIG. 7, to have a structure in which plug electrodes 341 are stacked directly on plug electrodes 321 in order to be connected to one another across the capacitor stage difference. However, the structure of directly stacking the plugs has a problem in that the process of forming via holes in the second interlayer dielectric film 370 allows only a small margin for mask alignment differences and therefore is highly difficult.

On the other hand, a method that uses dummy capacitors is known as a means to solve such problems as described in Japanese Laid-open Patent Application 2003-174145. By the method that uses dummy capacitors, a lower electrode film (described as an “upper electrode relay section” in Japanese Laid-open Patent Application 2003-174145) can be provided with a large plane area, such that a large margin can be given for mask alignment differences in the photolithography.

However, because the level of difficulty in micro-processing of ferroelectric capacitors including dummy capacitors is high and miniaturization lags behind, as compared with an ordinary logic circuit manufacturing process, contacts cannot be densely arranged by the method that uses dummy capacitors. For this reason, in embedded memories in particular, miniaturization of logic regions can possibly be obstructed by the arrangement rule for dummy capacitors.

Furthermore, the method using dummy capacitors also has a problem in that an increase in contact resistance cannot be avoided because contacts are made through the lower electrode film. In general, a relatively high resistant material, such as an oxidation prevention layer, is used as the lower electrode film for preventing oxidation of plug electrodes formed therebelow. Accordingly, the resistance of all wiring patterns connecting through the dummy capacitors is raised, which may possibly lead to a reduction in the operation speed of devices and an increase in the power consumption.

Therefore, the present invention has been made in view of such unsolved problems of the conventional technology described above.

### OBJECTS OF THE INVENTION

It is an object of the present invention to provide a method for manufacturing a semiconductor memory that has a large margin for mask alignment differences in photolithography.

It is another object of the present invention to provide a memory manufacturing method suitable for miniaturizing an element region for elements other than memory elements, and to provide such a semiconductor device.

### SUMMARY OF THE INVENTION

To achieve the objects described above, a method for manufacturing a semiconductor device in accordance with the present invention pertains to a method for manufacturing a semiconductor device having a memory element region and another element region for elements other than memory elements on a substrate, and is characterized in comprising: a step of forming a first interlayer dielectric film on the substrate; a step of forming a first opening section in the first interlayer dielectric film reaching the substrate by etching the first interlayer dielectric film over the memory element region; a step of forming a second opening section in the first interlayer dielectric film reaching the substrate by etching the first interlayer dielectric film over the another element region; a step of forming a first plug electrode in the first opening section and a second plug electrode in the second opening section; a step of forming a ferroelectric capacitor that covers the first plug electrode on the first interlayer dielectric film over the memory element region, after forming the first plug electrode and the second plug electrode; a step of forming a wiring pattern that covers the second plug electrode on the first interlayer dielectric film over the another element region; a step of forming a second interlayer dielectric film on the first interlayer dielectric film with the ferroelectric capacitor and the wiring pattern formed thereon; a step of forming a third opening section in the second interlayer dielectric film reaching the wiring pattern by etching the second interlayer dielectric film over the another element region; and a step of forming a third plug electrode in the third opening section.

Here, the ferroelectric capacitor includes, for example, a lower electrode film, a ferroelectric film and an upper electrode film. The lower electrode film and the upper electrode film are composed of a conductive material, such as, for example, platinum, iridium and the like. Also, the ferroelectric film is preferably a crystalline film having a perovskite structure, such as, for example, PZT (PbZr₁₋ₓTiₓO₃), SBT (SrBi₂Ta₂O₉) or the like. Furthermore, the wiring pattern is composed of a conductive material having a low resistance, such as, for example, aluminum. Also, the method for manufacturing a semiconductor device in accordance with the first embodiment includes a case in which the step of forming the first opening section and the step of forming the second opening section are conducted at the same time, and a case in which they are conducted separately.

In the step of forming the third opening section, an opening section of a mask can be aligned on the wiring pattern that covers the second plug electrode, but not on the second plug electrode, such that a large margin can be given for mask alignment differences in the photolithography. Also, the plug electrodes having a laminated structure in which the second plug electrode and the third plug electrode are stacked across the wiring pattern in a direction perpendicular to the substrate can be made to have a small occupancy area with respect to the substrate in a horizontal direction thereof, such that the plug electrodes having the laminated structure with the wiring patterns interposed between them can be densely arranged on the substrate. Accordingly, this can contribute to miniaturization of the another element region. Furthermore, by using a conductive material of low resistance such as aluminum for the wiring patterns, the resistance between the second plug electrode and the third plug electrode can be lowered.

Alternatively, after a plurality of the first opening sections and a plurality of the first plug electrodes are formed, and the plurality of the first plug electrodes and the second plug electrodes are formed: a step of forming a ferroelectric capacitor covering one of the first plug electrodes and a dummy capacitor covering another of the first plug electrodes on the first interlayer dielectric film over the memory element region; a step of etching a part of an upper electrode film and a part of a ferroelectric film of the dummy capacitor, to expose a part of a lower electrode film of the dummy capacitor through the upper electrode film; a step of forming the second interlayer dielectric film over the first interlayer dielectric layer after the wiring pattern is formed, to cover the wiring, the ferroelectric capacitor and the dummy capacitor; a step of etching the second interlayer dielectric film over the dummy capacitor to form a fourth opening section in the second interlayer dielectric film, which reaches the lower electrode film of the dummy capacitor; and a step of forming a fourth plug electrode in the fourth opening section.

Here, the dummy capacitor has the same structure as before, and includes a lower electrode film, a ferroelectric film and an upper electrode film. Its difference from a ferroelectric capacitor lies in its usage method, wherein the ferroelectric capacitor is used as a capacitor, but the dummy capacitor is not used as a capacitor. For example, the dummy capacitor is formed with an opening section in its upper electrode film (i.e. upper electrode plate) and ferroelectric film (i.e. dielectric insulator), which reaches its lower electrode film (i.e. lower electrode plate), and is used like a local wiring pattern when a plug electrode is formed in the opening section.

By this method, the ferroelectric capacitor and the dummy capacitor can be formed to have generally the same thickness, and a part of the dummy capacitor can remained even after the fourth opening section is formed. Accordingly, this contributes to planarization of the second interlayer dielectric film over the memory element region.

The step of forming the ferroelectric capacitor covering one of the first plug electrodes and a dummy capacitor covering another of the first plug electrodes on the first interlayer dielectric film over the memory element region, may further include: a step of successively forming a lower electrode film, a ferroelectric film and an upper electrode film on the first interlayer dielectric film where the plurality of first plug electrodes and the second plug electrodes are formed; a step of successively etching the upper electrode film, the ferroelectric film and the lower electrode film to form a ferroelectric capacitor covering the one of the first plug electrodes and a dummy capacitor covering the another of the first plug electrodes on the first interlayer dielectric film over the memory element region, and leaving the upper electrode film, the ferroelectric film and the lower electrode film at least on the second plug electrode; a step of heat-treating in an oxygen atmosphere the substrate where the ferroelectric capacitor and the dummy capacitor are formed, and the upper electrode film, the ferroelectric film and the lower electrode film remain at least on the second plug electrode; and a step of removing the upper electrode film, the ferroelectric film and the lower electrode film from above the second plug electrode.

Here, the step of heat-treating the substrate in an oxygen atmosphere is a step whose main purpose is to recover the ferroelectric film from etching damages or the like that may possibly be inflicted upon successive etching of the upper electrode film, the ferroelectric film and the lower electrode film.

When the substrate is heat-treated in an oxygen atmosphere, oxygen can be prevented from reaching the first and second plug electrodes, and oxidation thereof can be prevented.

A method for manufacturing a semiconductor device in accordance with a fourth embodiment of the present invention is characterized in comprising, in the method for manufacturing a semiconductor device in accordance with the third embodiment, a step of forming a dielectric film equipped with a hydrogen barrier function on upper and side surfaces of the ferroelectric capacitor, after the heat-treatment but before the step of forming the second interlayer dielectric film.

By such a structure, hydrogen can be prevented to some extent from reaching the ferroelectric capacitor, and therefore the ferroelectric film can be made not to be reduced.

Further alternatively, before the step of forming the wiring pattern, the manufacturing process my having a step of etching the dielectric film formed on the upper electrode film of the ferroelectric capacitor to thereby expose at least a part of the upper electrode film through the dielectric film; and a step of forming a local wiring pattern on the ferroelectric capacitor to thereby connect the local wiring pattern to the part of the upper electrode film exposed through the dielectric film.

Here, the local wiring pattern is a conductive film equipped with a hydrogen barrier function, such as, for example, an iridium oxide film or the like, or a laminated structure film including a conductive film equipped with such a hydrogen barrier function.

In this way, an area above the ferroelectric capacitor can be protected by the local wiring pattern from the time prior to the step of forming a wiring, such that process damage to the ferroelectric capacitor can be reduced. Also, by forming the local wiring pattern from a conductive film equipped with a hydrogen barrier function such as an iridium oxide film or the like, hydrogen can be better prevented from reaching the ferroelectric capacitor, which contributes to prevention of reduction of the ferroelectric film.

In summary, a semiconductor device in accordance with the present invention pertains to a semiconductor device having a memory element region and another element region for elements other than memory elements on a substrate, and is characterized in comprising: a first interlayer dielectric film provided on the substrate; a first opening section provided in the first interlayer dielectric film, reaching the substrate over the memory element region; a second opening section provided in the first interlayer dielectric film reaching the substrate over the another element region; a first plug electrode provided in the first opening section; a second plug electrode provided in the second opening section; a ferroelectric capacitor that is provided on the first interlayer dielectric film over the memory element region and covers the first plug electrode; a wiring pattern that is provided on the first interlayer dielectric film over the another element region and covers the second plug electrode; a second interlayer dielectric film provided on the first interlayer dielectric film; a third opening section that is provided in the second interlayer dielectric film and reaches the wiring; and a third plug electrode provided in the third opening section.

According to such a structure, the third opning section is provided on the wring that covers the second plug electrode, and not on the second plug electrode, such that a large margin can be given for mask alignment differences in photolithography. Also, the plug electrodes having a laminated structure in which the second plug electrode and the third plug electrode are stacked across the wiring pattern in a direction perpendicular to the substrate can be made to have a small occupancy area with respect to the substrate in a horizontal direction thereof, such that the plug electrodes having the laminated structure with the wiring patterns interposed between them can be densely arranged on the substrate. Accordingly, this can contribute to miniaturization of the other element region. Furthermore, by using a conductive material of low resistance such as aluminum for the wiring patterns, the resistance between the second plug electrode and the third plug electrode can be lowered.

Alternatively, a semiconductor device in accordance with the present invention may have: a plurality of the first opening sections and a plurality of the first plug electrodes provided in the first opening sections; the ferroelectric capacitor that is provided on the first interlayer dielectric film over the memory element region and covers one of the first plug electrodes; a dummy capacitor that is provided on the first interlayer dielectric film over the memory element region and covers another of the first plug electrodes; and the second interlayer dielectric film provided on the first interlayer dielectric film, wherein a fourth opening section reaching a lower electrode film of the dummy capacitor is provided in the second interlayer dielectric film above the dummy capacitor, and in an upper electrode film and a ferroelectric film of the dummy capacitor, and a fourth plug electrode is provided in the fourth opening section.

By such a structure, the ferroelectric capacitor and the dummy capacitor can be formed in generally the same thickness, which can contribute to planarization of the second interlayer dielectric film over the memory element region.

Other objects and attainments together with a fuller understanding of the invention will become apparent and appreciated by referring to the following description and claims taken in conjunction with the accompanying drawings.

### BRIEF DESCRIPTION OF THE DRAWINGS

In the drawings wherein like reference symbols refer to like parts.

FIG. 1 A cross-sectional view showing an exemplary structure of a semiconductor device in accordance with the present invention.

FIGS. 2(A) to 2(D) show process steps for manufacturing the semiconductor device of FIG. 1.

FIGS. 3(A) to 3(D) show additional process steps for manufacturing the semiconductor device of FIG. 1.

FIG. 4 A cross-sectional view showing a variation over the semiconductor device 100 of FIG. 1 wherein an exemplary structure of a an additional wiring pattern layer between top wiring layer 55 and the upper electrode film 33 of ferroelectric capacitor 30.

FIGS. 5(A) to 5(D) show process steps for manufacturing the semiconductor device of FIG. 4.

FIG. 6 Process figures showing the method for manufacturing the semiconductor device 200.

FIG. 7 A cross-sectional view showing an exemplary structure of a semiconductor device 300 in accordance with a conventional example.

### DESCRIPTION OF THE PREFERRED EMBODIMENTS

A method for manufacturing a semiconductor device, and a semiconductor device in accordance with the present invention are described below with reference to the accompanying drawings.

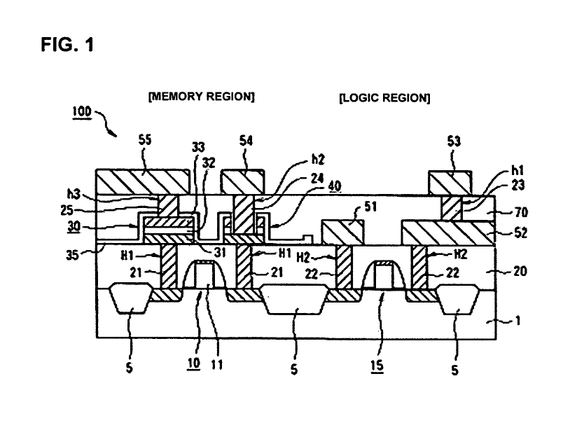

FIG. 1 is a cross-sectional view showing an exemplary structure of a semiconductor device 100 in accordance with a first embodiment of the present invention. The semiconductor device 100 is a so-called embedded FeRAM that has a plurality of ferroelectric capacitors 30 in a memory region of a semiconductor substrate 1, and a logic circuit in a logic region of the semiconductor substrate 1.

As shown in FIG. 1, semiconductor device 100 includes a cell selection MOS transistor (i.e select transistor) 10 formed in the memory region of semiconductor substrate 1, a logic MOS transistor 15 formed in the logic region of semiconductor substrate 1, element isolation layers (i.e. isolation regions) 5, and a first interlayer dielectric film 20 provided over the semiconductor substrate 1. Semiconductor substrate 1 is, for example, a silicon substrate. As shown in FIG. 1, a plurality of first contact holes H1 that reach a surface of the semiconductor substrate 1 are provided in first interlayer dielectric film 20 over the memory region of semiconductor substrate 1. Also, a plurality of second contact holes H2 that reach the surface of the semiconductor substrate 1 are provided in the first interlayer dielectric film 20 over the logic region of semiconductor substrate 1.

Also, semiconductor device 100 includes first plug electrodes (i.e. vias) 21 provided in the respective contact holes H1, second plug electrodes (i.e. vias) 22 provided in the plural contact holes H2, respectively, a ferroelectric capacitor 30 that is provided on the first interlayer dielectric film 20 over the memory region of semiconductor substrate 1 and covers one of the first plug electrodes 21, a dummy capacitor 40 that is provided on the first interlayer dielectric film 20 over the memory region of semiconductor substrate 1 and covers the other of the first plug electrodes 21, and a plurality of (first, second) wiring patterns 51 and 52 that are provided on the first interlayer dielectric film 20 over the logic region of semiconductor substrate 1 and cover the second plug electrodes 22.

FIG. 1 shows only a single ferroelectric capacitor 30 and dummy capacitor 40, but semiconductor device 100 may have a plurality of ferroelectric capacitors 30 and a plurality of dummy capacitors 40. Each of ferroelectric capacitor 30 and dummy capacitor 40 is composed of a lower electrode film 31, a ferroelectric film 32 and an upper electrode film 33. The lower electrode film 31 and the upper electrode film 33 are formed from, for example, platinum (Pt), iridium (Ir) or the like, or a conductive film with a laminated structure of stacked layers of these materials. The ferroelectric film 32 consists of, for example, SBT, PZT, or the like.

Also, as shown in FIG. 1, the semiconductor device 100 includes a dielectric film 35 provided in a manner to cover the ferroelectric capacitor 30 and the dummy capacitor 40, and a second interlayer dielectric film 70 provided on the first interlayer dielectric film 20 in a manner to cover the dielectric film 35 and the first and second wiring patterns 51 and 52. As shown in FIG. 1, first-third via holes h1-h3 are provided in the second interlayer dielectric film 70 and the like.

Among these via holes, the first via hole h1 is provided in the second interlayer dielectric film 70 over the logic region of semiconductor substrate 1, and is formed in a manner to reach a surface of the second wiring pattern 52. Also, the second via hole h2 is provided in a manner to extend from the second interlayer dielectric film 70 over the memory region of semiconductor substrate 1 to the ferroelectric film 32 of the dummy capacitor 40, and is formed in a manner to reach a surface of the lower electrode film 31 of the dummy capacitor 40. Furthermore, the third via hole h3 is provided in the second interlayer dielectric film 70 in the memory region of semiconductor substrate 1, and is formed in a manner to reach a surface of the upper electrode 33 of the ferroelectric capacitor 30.

Further, the semiconductor device 100 includes third-fifth plug electrodes 23-25 that are provided in the respective via holes h1-h3, and third-fifth wiring patterns 53-55. As shown in FIG. 1, the third-fifth wiring patterns 53-55 are formed on the second interlayer dielectric film 70, the third wiring pattern 53 covers the third plug electrode 23, the fourth wiring pattern 54 covers the fourth plug electrode 24, and the fifth wiring pattern 55 covers the fifth plug electrode 25.

The semiconductor device 100 shown in FIG. 1 may further include, for example, a third interlayer dielectric film (not shown) on the second interlayer dielectric film 70, and bit lines (not shown) on the third interlayer dielectric film. The fourth wiring pattern 54, the fourth plug electrode 24, and the first plug electrode 21 connected to the fourth plug electrode 24 through the dummy capacitor 40 shown in FIG. 1 would be connected to the not shown bit line. Also, in this semiconductor device 100, for example, the fifth wiring pattern 55 is preferably a plate line, and the gate electrode 11 of the cell selection MOS transistor 10 is preferably a word line. Next, a method for manufacturing the semiconductor device 100 is described.

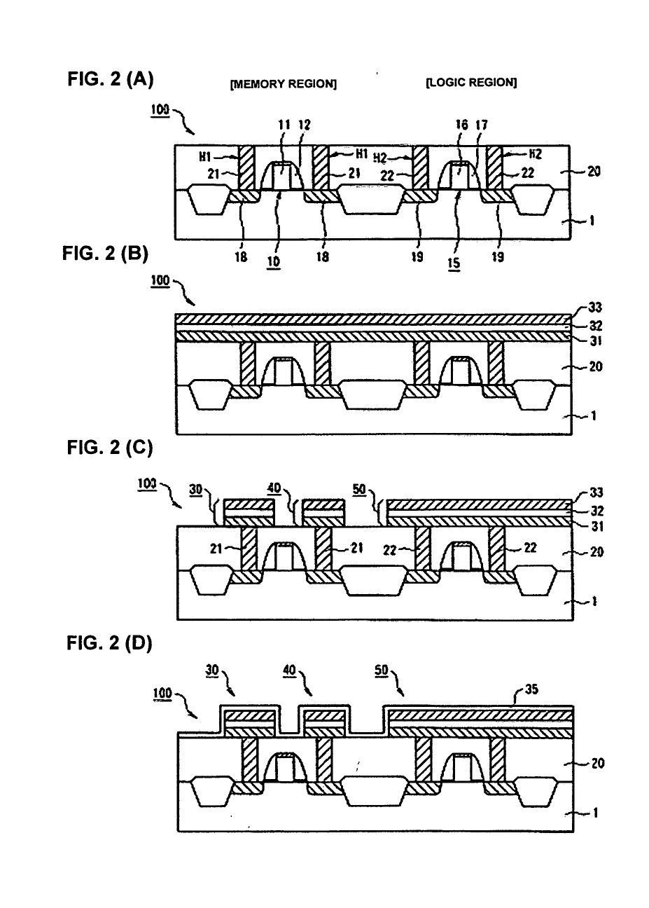

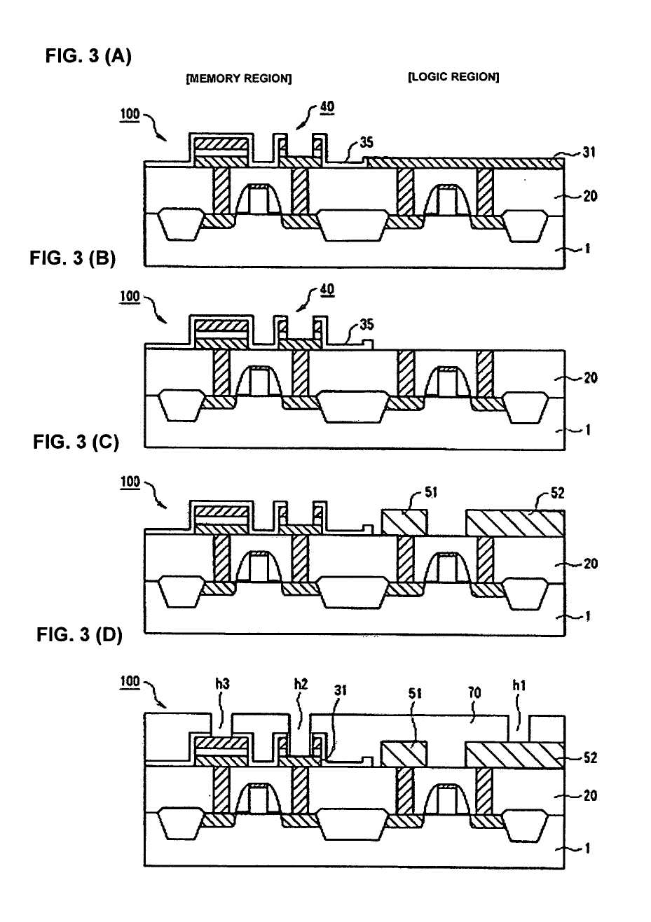

FIG. 2 (A)-FIG. 3 (D) are process figures illustrating a method for manufacturing semiconductor device 100. Process steps up to the point where first and second plug electrodes 21 and 22 are formed in FIG. 2 (A) are similar to those of a typical IC manufacturing process.

More specifically, first, a gate dielectric film (not shown) is formed on a semiconductor substrate 1 by a thermal oxidation method. Next, a polysilicon film including an impurity such as phosphorous or the like is formed in the gate dielectric film by CVD (chemical vapor deposition). Then, the polysilicon film is patterned in a predetermined shape by using a photolithography technique and a dry-etching technique, to form gate electrodes 11 and 16 shown in FIG. 2 (A).

Next, sidewall spacers 12 and 17 are formed; and the gate electrodes 11 and 16 with the sidewall spacers 12 and 17 formed respectively thereon are used as a mask to thereby inject ions of an impurity, such as, for example, phosphorous in the semiconductor substrate 1, whereby source and drain (i.e. S/D) regions 18, 19 are formed in the semiconductor substrate on both sides of a region (channel region) below each of the gate electrodes 11 and 16. In this manner, a cell selection MOS transistor (i.e. select transistor) 10 is formed on the semiconductor substrate 1 in a memory region of semiconductor substrate 1, and a logic MOS transistor 15 is formed on the semiconductor substrate 1 in a logic region of semiconductor substrate 1.

Next, as shown in FIG. 2 (A), a first interlayer dielectric film 20 is formed over the semiconductor substrate 1 in a manner to cover cell selection MOS transistor 10 and logic MOS transistor 15. The first interlayer dielectric film 20 may be formed by, for example, CVD. The first interlayer dielectric film 20 may be, for example, a silicon oxide film, and its thickness is, for example, about 800 nm.

Next, by using a photolithography technique and a dry-etching technique, first and second contact holes H1 and H2 are formed over the S/D regions 18 of the cell selection MOS transistor 10 and over the S/D regions 19 of the MOS transistor 15 in the logic region, respectively.

Next, as shown in FIG. 2 (A), first and second plug electrodes 21 and 22 composed of a high melting point metal film, such as, tungsten (W) or the like are formed in the first and second contact holes H1 and H2, respectively. The first and second plug electrodes 21 and 22 may be formed through, for example, depositing a W film (i.e. tungsten film) on the first interlayer dielectric film 20 by CVD, and planarizing the W film by CMP (chemical mechanical polish).

Next, as shown in FIG. 2 (B), a lower electrode film 31 of Pt (platinum) or the like is formed on the first interlayer dielectric film 20. The lower electrode film 31 may be formed by, for example, using a sputtering method. The thickness of the lower electrode 31 upon completion is, for example, about 150-250 nm. Next, a raw material liquid of an SBT-based (such as SrBi₂Ta₂O₉) or PZT-based (such as PbZr₁₋ₓTiₓO₃) ferroelectric film 32 is coated on the lower electrode film 31 by a spin coat method. Then, the coated raw material liquid is dried in a dry atmosphere at about 400° C.

The steps of coating and drying are repeated several times to form the ferroelectric film 32 to a thickness of, for example, about 100-150 nm. Next, the semiconductor substrate 1 with the ferroelectric film 32 formed thereon is heat-treated, for example, in an atmosphere containing oxygen at about 700° C., to crystallize the ferroelectric film 32. Then, an upper electrode film 33 of Pt or the like is formed on the crystallized ferroelectric film 32. The upper electrode film 33 may be formed by using, for example, a sputtering method. Next, by using a photolithography technique and a dry-etching technique, the upper electrode film 33, the ferroelectric film 32 and the lower electrode film 31 are patterned.

As a result, as shown in FIG. 2 (C), a ferroelectric capacitor 30 and a dummy capacitor 40 are formed on the first interlayer dielectric film 20 over the memory region. Also, as shown in FIG. 2 (C), the upper electrode film 33, the ferroelectric film 32 and the lower electrode film 31 are remained on the first interlayer dielectric film 20 over the logic region of semiconductor substrate 1. Hereunder, the upper electrode film 33, the ferroelectric film 32 and the lower electrode film 31 that remain over the logic region of semiconductor substrate 1 are also collectively called a dummy region 50.

Next, the semiconductor substrate 1 on which the ferroelectric capacitor 30 and the dummy capacitor 40 are formed on the first interlayer dielectric film 20 over the memory region, and the dummy region 50 is formed on the first interlayer dielectric film 20 over the logic region is heat-treated in an oxygen atmosphere. This heat treatment is a treatment for recovery of the ferroelectric film 32 from possible etching damages and the like inflicted thereon when the upper electrode film 33, the ferroelectric film 32 and the lower electrode film 31 were successively etched in the step of FIG. 2 (B).

In the heat treatment step conducted in the oxygen atmosphere, because the first plug electrodes 21 is covered by the ferroelectric capacitor 30 or the dummy capacitor 40, and the second plug electrode 22 is covered by the dummy region 50, oxygen is prevented from reaching the first and second plug electrodes 21 and 22, and oxidation thereof can thereby be prevented.

Next, as shown in FIG. 2 (D), a dielectric film 35 is formed over the first interlayer dielectric film 20 where ferroelectric capacitor 30, dummy capacitor 40, and dummy region 50 are formed. The dielectric film 35 may be formed by, for example, reactive sputtering. The dielectric film 35 may be, for example, alumina (Al₂O₃) equipped with a hydrogen barrier function, and may have a thickness of about 50 nm to 70 nm. As shown in FIG. 2 (D), upper surfaces and side surfaces of ferroelectric capacitor 30, dummy capacitor 40 and dummy region 50 are covered by the dielectric film 35.

As shown in FIG. 3 (A), by using a photolithography technique and a dry-etching technique, the dielectric film 35 in a portion above a center area of the dummy capacitor 40 is removed, and further an exposed portion of the upper electrode film 33 and the ferroelectric film 32 under the dielectric film 35 are removed. However, the dielectric film 35 on a circumferential area of the dummy capacitor 40, and the upper electrode film 33 and the ferroelectric film 32 that are covered by the dielectric film 35 in the circumferential area are left without being etched.

By this, the center area of the lower electrode film 31 of the dummy capacitor 40 is exposed through the dielectric film 35. Also, at this time, the dielectric film 35 on dummy region 50, and the upper electrode film 33 and the ferroelectric film 32 composing the dummy region 50 are removed. Then, by using a photolithography technique and a dry-etching technique, the lower electrode film 31 is removed from the logic region, as shown in FIG. 3 (B).

Next, as shown in FIG. 3 (C), first and second wiring patterns 51 and 52 are formed on the first interlayer dielectric film 20 in the logic region of semiconductor substrate 1. The first and second wiring patterns 51 and 52 may be formed, for example, by forming a conductive film using a sputtering technique, and patterning the conductive film by a photolithography technique and a dry-etching technique. The conductive film may be, for example, an aluminum film or an aluminum alloy film.

As shown in FIG. 3 (D), a second interlayer dielectric film 70 is formed on the first interlayer dielectric film 20 on which the first and second wiring patterns 51 and 52 are formed. The second interlayer dielectric film 70 may be formed by, for example, CVD. The second interlayer dielectric film 70 may be, for example, a silicon oxide film, and its thickness is preferably about 1500 nm. After the second interlayer dielectric film 70 is formed, a CMP processing is applied to the second interlayer dielectric film 70 to planarize its surface.

Next, by using a photolithography technique and a dry-etching technique, as shown in FIG. 3 (D), a first via hole h1 that reaches a surface of the second wiring pattern 52, a second via hole h2 that reaches a surface of the lower electrode film 31 of the dummy capacitor 40, and a third via hole h3 that reaches a surface of the upper electrode film 33 of the ferroelectric capacitor 30 are formed at the same time.

It is noted here that, as shown in FIG. 3 (D), the second via hole h2 is formed such that an aperture inner wall of the center portion of the upper electrode film 33 and an aperture inner wall of the center portion of the ferroelectric film 32 formed by the previous etching are left covered by the second interlayer dielectric film 70, respectively. Further, the third via hole h3 is formed by removing not only the second interlayer dielectric film 70 but also its base, the dielectric film 35.

Next, third-fifth plug electrodes 23-25 (see FIG. 1) composed of tungsten (W) or the like are formed in the first-third via holes h1-h3, respectively. The third-fifth plug electrodes 23-25 may be formed, in a manner similar to the first and second plug electrodes 21 and 22, for example, through deposition of a W film by CVD, and planarization of the W film by CMP.

Then, third-fifth wiring patterns 53-55 (see FIG. 1) are formed on the second interlayer dielectric film 70 where the third-fifth plug electrodes 23-25 are formed, respectively. The third-fifth wiring patterns 53-55 may be formed, in a manner similar to the first and second wiring patterns 51 and 52, for example, through formation of a conductive film by using a sputtering technique, and patterning of the conductive film by using a photolithography technique and a dry-etching technique. The conductive film may be, for example, an aluminum film or an aluminum alloy film. As a result, the semiconductor device 100 shown in FIG. 1 is completed.

According to the method for manufacturing the semiconductor device 100 in accordance with the first embodiment of the present invention, contacts may be formed using dummy capacitors 40 in the memory region of semiconductor substrate 1, which is an area with minimum space requirements. Additionally, the upper electrode film 33, the ferroelectric film 32 and the lower electrode film 31 may be left as the dummy region 50 in the logic region of semiconductor substrate 1 until after the heat treatment step that is conducted at the time of forming the capacitor. Then, after the heat treatment step, the dummy region 50 is removed to expose the second plug electrodes 22, and the second wiring pattern 52 is formed directly thereon. In this way, when miniaturization of the semiconductor device 100 is further advanced, the difficulty associated with the structure of the conventional example wherein plug electrodes are stacked are not encountered.

However, in the method in which the dummy region 50 is provided, the second wiring pattern 52 may be provided directly on the second plug electrode 22, and therefore it may require the forming of dot patterns in pad formation for directly raising pads to wiring patterns further above, which may not be suitable in view of micro-processing. It is noted here that the pad is a general term for wiring patterns each having a squire shape or a similar planar shape. In the present invention, pads are wiring patterns that selectively connect pairs of upper and lower plug electrodes formed generally in the same plane positions (or levels, i.e. at similar levels). Also, the dot pattern is a square pattern or a circular pattern formed in a plane size that is close to the minimum processing size.

For this reason, for contacts with bit lines in which contacts are raised generally up to the second layer from the substrate side, contacts using the dummy capacitors 40 are used. In the case of a contact using the dummy capacitor 40, although an area similar to that of the ferroelectric capacitor 30 composing a memory cell is required, any area loss can be minimized by limiting their location to the memory region of semiconductor substrate 1.

Also, in the present invention, wiring patterns including dummy wiring patterns for adjusting step differences can be provided over the entire surface except the capacitor array region (i.e. memory region of semiconductor substrate 1). Consequently, planarization of step differences created by the ferroelectric capacitors 30 becomes easier.

In the first embodiment, the semiconductor substrate 1 corresponds to a substrate of the present invention, the memory region of semiconductor substrate 1 corresponds to a memory region of the present invention, and the logic region of semiconductor substrate 1 corresponds to another element region for elements other than memory elements of the present invention. Also, the contact hole H1 corresponds to a first opening section of the present invention, and the contact hole H2 corresponds to a second opening section of the present invention. Furthermore, the second wiring pattern 52 corresponds to a wiring pattern of the present invention, and the first via hole h1 corresponds to a third opening section of the present invention. Also, the second via hole h2 corresponds to a fourth opening section of the present invention, and the dielectric film 35 corresponds to a dielectric film equipped with a hydrogen barrier function of the present invention.

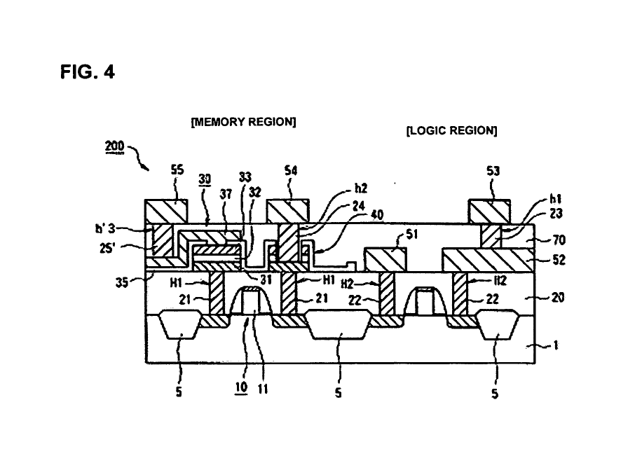

FIG. 4 is a cross-sectional view showing an exemplary structure of a semiconductor device 200 in accordance with a second embodiment of the present invention. In FIG. 4, parts having substantially the same functions as those of the semiconductor device 100 shown in FIG. 1 are appended with the same reference numbers, and their detailed description is omitted. As shown in FIG. 4, the semiconductor device 200 includes a local wiring pattern 37 that extends from an area above the dielectric film 35 on the ferroelectric capacitor 30 to an area above dielectric film 35 at a position removed from the ferroelectric capacitor 30. Local wiring pattern 37 and the upper electrode 33 of the ferroelectric capacitor 30 are connected to each other. Also, local wiring pattern 37 is connected to a fifth plug electrode 25′ formed in a third via hole h′3 at a position removed from ferroelectric capacitor 30. Next, a method for manufacturing the semiconductor device 200 is described.

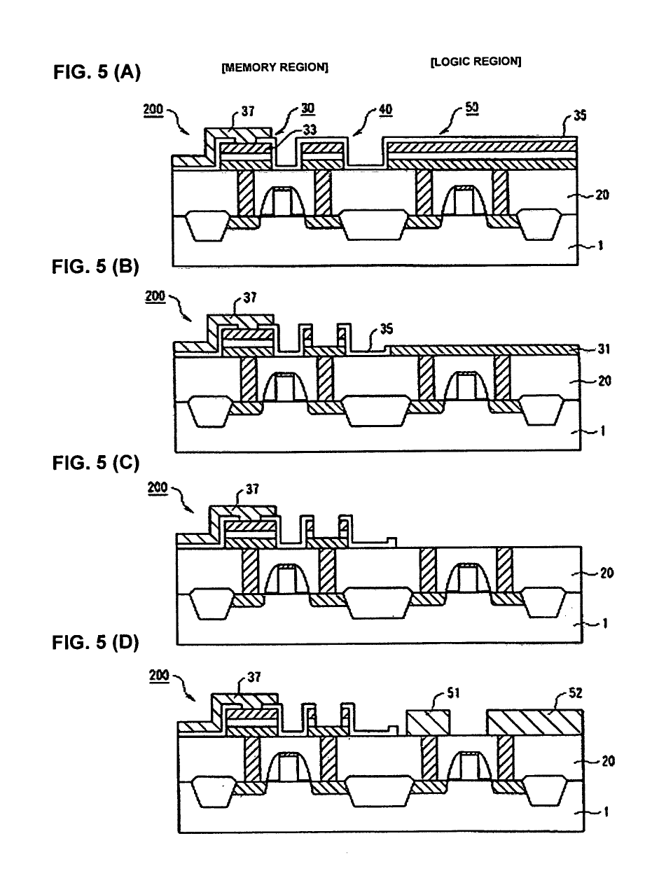

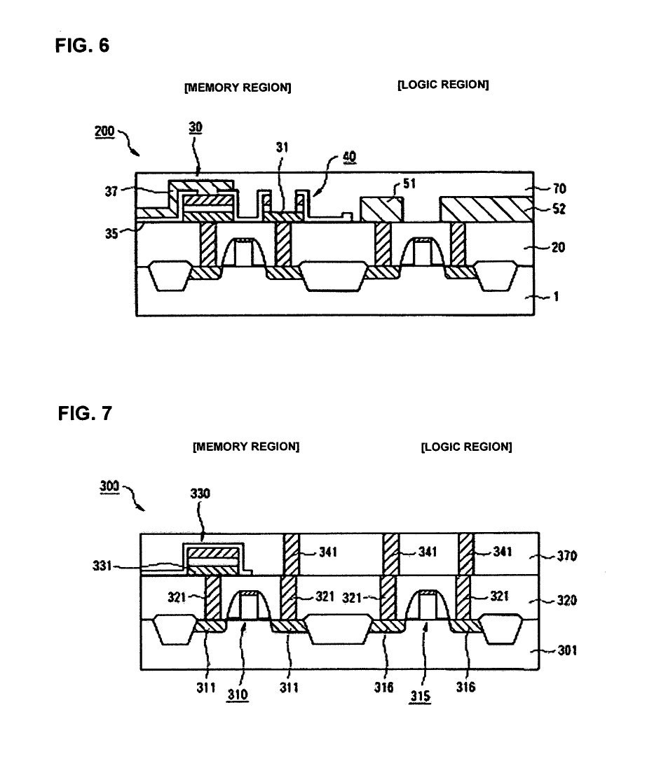

FIGS. 5(A) to 5(D) and FIG. 6 are show process steps in a method for manufacturing semiconductor device 200. Referring to FIG. 5 (A), the manufacturing steps up to the step of forming dielectric film 35 of Al₂O₃, or the like, are similar to the manufacturing steps of semiconductor device 100 shown in FIG. 2 (A)-FIG. 2 (D).

As shown in FIG. 5 (A), the dielectric film 35 is formed on a first interlayer dielectric film 20 to a thickness of, for example, about 50-70 nm in a manner so as to cover ferroelectric capacitor 30, dummy capacitor 40 and dummy region 50 that consists of a stacked, and unlabeled, upper electrode film, ferroelectric film and lower electrode. A part of dielectric film 35 on the ferroelectric capacitor 30 is then selectively removed. It is noted here that dielectric film 35 is not removed from the entire surface over the ferroelectric capacitor 30, but dielectric film 35 is removed from a center area of ferroelectric capacitor 30, and a circumferential area of dielectric film 35 is left. The selective removal of dielectric film 35 may be conducted by using, for example, a photolithography technique and an etching technique.

Next, as shown in FIG. 5 (A), the local wiring pattern 37 is formed extending from an area on ferroelectric capacitor 30 to a position on dielectric film 35 distant from ferroelectric capacitor 30. Upper electrode film 33 of ferroelectric capacitor 30, which is exposed through dielectric film 35, is covered by local wiring pattern 37. Local wiring pattern 37 may, for example, be formed by forming a conductive film using a sputtering technique, and patterning the conductive film by using a photolithography technique and a dry-etching technique. The conductive film may be, for example, an iridium oxide film or a laminated structure film including an iridium oxide film.

Next, by using a photolithography technique and a dry-etching technique, dielectric film 50 is removed from above dummy region 50, and then the upper electrode film and the ferroelectric film, which are part of dummy region 50, are removed, as shown in FIG. 5 (B). Furthermore, the lower electrode film 31, which is also a part of dummy region 50, is also removed from the first interlayer dielectric film 20 over the logic region of semiconductor substrate 1, as shown in FIG. 5 (C).

Next, as shown in FIG. 5 (D), first and second wiring patterns 51 and 52 are formed on the first interlayer dielectric film 20 over the logic region of semiconductor substrate 1. The first and second wiring patterns 51 and 52 may be formed, for example, through forming a conductive film by using a sputtering technique, and patterning the conductive film by using a photolithography technique and a dry-etching technique. The conductive film may be, for example, an aluminum film or an aluminum alloy film.

Next, as shown in FIG. 6, a second interlayer dielectric film 70 is formed on the first interlayer dielectric film 20. First and second wiring patterns 51 and 52 are formed on second interlayer dielectric film 70. Second interlayer dielectric film 70 may be formed by, for example, CVD. The second interlayer dielectric film 70 may be, for example, a silicon oxide film, and its thickness is, for example, about 1500 nm. After the second interlayer dielectric film 70 has been formed, a CMP processing is applied to the second interlayer dielectric film 70 to planarize its surface.

Next, by using a photolithography technique and a dry-etching technique, a first via hole h1 (see FIG. 4) that reaches a surface of the second wiring pattern 52, a second via hole h2 (see FIG. 4) that reaches a surface of the lower electrode film 31 of the dummy capacitor 40, and a third via hole h′3 (see FIG. 4) that reaches a surface of the local wiring pattern at a position removed from the ferroelectric capacitor 30 are formed. It is noted here that the second via hole h2 is formed such that an aperture inner wall of the center portion of the upper electrode film 33 and an aperture inner wall of the center portion of the ferroelectric film 32 formed by the previous etching are left covered by the second interlayer dielectric film 70, respectively.

Then, third-fifth plug electrodes 23, 24 and 25′ (see FIG. 4) composed of tungsten (W) or the like are formed in the first-third via holes h1-h3, respectively. The third-fifth plug electrodes 23, 24 and 25′ may be formed, for example, through deposition of a W film by CVD, and planarization of the W film by CMP.

Then, third-fifth wiring patterns 53-55 (see FIG. 4) are formed on the second interlayer dielectric film 70 where the third-fifth plug electrodes 23, 24 and 25′ are formed, respectively. The third-fifth wiring patterns 53-55 may be formed through, for example, formation of a conductive film by using a sputtering technique, and patterning of the conductive film by using a photolithography technique and a dry-etching technique. The conductive film may be, for example, an aluminum film or an aluminum alloy film. As a result, the semiconductor device 400 shown in FIG. 4 is completed.

According to the method for manufacturing the semiconductor device in accordance with the second embodiment of the present invention, the local wiring pattern 37 is formed, which extends from an area above the upper electrode film 33 of the ferroelectric capacitor 30 exposed through the dielectric film 35 to an area over the dielectric film 35 at a position removed from the ferroelectric capacitor 30, and the fifth plug electrode 25′ is formed on the local wiring pattern 37 at a position removed from the ferroelectric capacitor 30.

The local wiring pattern 37 may be, for example, an iridium oxide film or a laminated structure film including an iridium oxide film. The local wiring pattern 37 has a function to prevent hydrogen from diffusing into a lower layer (hydrogen barrier function). Also, the local wiring pattern 37 has a property that is hard to transfer process damages caused by, for example, dry-etching or the like to its lower layer.

With such a structure as described above, process damages (for example, etching damages caused by dry-etching or the like) to the ferroelectric capacitor 30 in steps to be conducted after the local wiring pattern 37 has been formed can be reduced, which can contribute to improvement of the yield and reliability of the semiconductor device 200. In particular, by forming the local wiring pattern 37 to cover the entire surface of the ferroelectric capacitor 40, process damages that may be inflicted from above can be effectively suppressed.

It is noted that, in the second embodiment, the case in which the dielectric film 35 composed of Al₂O₃ or the like is formed to a thickness of, for example, about 50-70 nm is described with reference to FIG. 5 (A). However, the dielectric film 35 may be formed thicker than the above, and the thickly formed dielectric film 35 may be planarized later by CMP. With this structure, the film formation of the local wiring pattern 37 and its patterning formation can be facilitated.

Also, in the second embodiment, in FIG. 5 (C), a dielectric protection film (not shown) may be provided on the first interlayer dielectric film 20 over the memory region in a manner to cover the local wiring pattern 37 and the dummy capacitor 40; and in this state, the first and second wiring patterns 51 and 52 may be formed on the first interlayer dielectric film 20 over the logic region. With this structure, etching damages that may be caused when the first and second wiring patterns 51 and 52 are formed can be received by the protection film, such that etching damages to the local wiring pattern 37 and the dummy capacitor 40 can be reduced.

The present invention brings about an effect to reduce the load in planarizing a FeRAM. In particular, in an embedded FeRAM, while multilayer wiring patterns may be required in a logic circuit portion (i.e. logic region of semiconductor substrate 1), it is considered that wiring patterns in 2-3 layers may be sufficient in a FeRAM cell array portion. In other words, step differences generated in the FeRAM cell array portion can be offset by wiring patterns in the logic circuit portion, and therefore the wiring layers can be effectively used.

While the invention has been described in conjunction with several specific embodiments, it is evident to those skilled in the art that many further alternatives, modifications and variations will be apparent in light of the foregoing description. Thus, the invention described herein is intended to embrace all such alternatives, modifications, applications and variations as may fall within the spirit and scope of the appended claims.

What is claimed is:

1. A method for manufacturing a semiconductor device having a first region for memory elements and a second region for elements other than said memory elements on a substrate, said method comprising:
forming a first interlayer dielectric film on the substrate;
forming a first opening section in the first interlayer dielectric film over said first region, said first opening being made to reach the substrate;
forming a second opening section in the first interlayer dielectric film over said second region, said second opening being made to reach the substrate;
forming a first plug electrode in the first opening section and a second plug electrode in the second opening section;
forming a ferroelectric capacitor on the first interlayer dielectric film, said ferroelectric capacitor covering and contacting said first plug electrode;
forming a first wiring pattern on the first interlayer dielectric film, said first wiring pattern covering and contacting said second plug electrode;
forming a second interlayer dielectric film on the first interlayer dielectric film and covering said ferroelectric capacitor and first wiring pattern;
forming a third opening section in the second interlayer dielectric film over said second region, said third opening reaching said first wiring pattern; and
forming a third plug electrode in said third opening section.

2. The method of claim 1, wherein:
a plurality of said first opening sections are formed in said first interlayer dielectric film over said first region;
a plurality of said first plug electrodes are formed in said plurality of first openings, on a one-to-one basis;
a plurality of said second opening sections are formed in said first interlayer dielectric film over said second region;
a plurality of second plug electrodes are formed in said plurality of second openings, on a one-to-one basis; and
said ferroelectric capacitor is formed covering one of said first plug electrodes;
said method further comprising:
forming a dummy capacitor consisting of a lower electrode film covered by a ferroelectric film covered by an upper electrode film, said dummy capacitor being formed to cover and contact another of said plurality of first plug electrodes;
etching a part of said upper electrode film and ferroelectric film to expose a part of said lower electrode film, wherein the second interlayer dielectric film covers the ferroelectric capacitor and the dummy capacitor;
etching the second interlayer dielectric film over the dummy capacitor to form in the second interlayer dielectric film a fourth opening section substantially over said exposed part of said lower electrode film; and
forming a fourth plug electrode to contact said exposed part of said electrode film through the fourth opening section.

3. The method of claim 2, wherein forming said ferroelectric capacitor and said dummy capacitor includes the following steps:
successively forming said lower electrode film, said ferroelectric film and said upper electrode film on the first interlayer dielectric film where the plurality of first plug electrodes and second plug electrodes are formed;
successively etching, in said first region, the upper electrode film, the ferroelectric film and the lower electrode film to form said ferroelectric capacitor and said dummy capacitor while leaving the upper electrode film, the ferroelectric film and the lower electrode film in tact at least over the second plug electrodes;
heat-treating, in an oxygen atmosphere, the substrate where the ferroelectric capacitor and dummy capacitor are formed while the upper electrode film, the ferroelectric film and the lower electrode film are still over the second plug electrodes; and
removing the upper electrode film, the ferroelectric film and the lower electrode film from over the second plug electrodes.

4. The method of claim 3, wherein a dielectric film having a hydrogen barrier function is formed on upper and side surfaces of the ferroelectric capacitor after the heat-treatment but before the second interlayer dielectric film is formed.

5. The method of claim 4, wherein before the first wiring pattern is formed, said dielectric film having a hydrogen barrier function is etched to expose at least a part of the upper electrode film of the ferroelectric capacitor; and
a second wiring pattern is formed to couple the exposed part of the upper electrode film of the ferroelectric capacitor.

6. A semiconductor device having a first region for memory elements and a second region for elements other than memory elements on a substrate, comprising:
a first interlayer dielectric film on the substrate;
a first opening section in the first interlayer dielectric film over said first region, said first opening section reaching the substrate;
a second opening section in the first interlayer dielectric film over said second region, said second opening section reaching the substrate;
a first plug electrode in the first opening section;
a second plug electrode in the second opening section;
a ferroelectric capacitor on the first interlayer dielectric film covering and contacting the first plug electrode;
a wiring pattern on the first interlayer dielectric film over said second region, said wiring pattern covering and contacting the second plug electrode;
a second interlayer dielectric film on the first interlayer dielectric film;
a third opening section in the second interlayer dielectric film, said third opening section reaching the wiring pattern; and
a third plug electrode in the third opening section.

7. The semiconductor device of claim 6, wherein:
said first opening section is one of a plurality of first opening sections; and
said first plug electrode is one of a plurality of first plug electrodes in respective first opening sections;
said semiconductor device further comprising:
a dummy capacitor on the first interlayer dielectric film over said first region, wherein said dummy capacitor covers and contacts another of said plurality of first plug electrodes, said dummy capacitor having an upper electrode film over a ferroelectric film over a lower electrode film;
a fourth opening section in the second interlayer dielectric film over the dummy capacitor, said fourth opening section penetrating the upper electrode and ferroelectric film of said dummy capacitor to reach the lower electrode film of the dummy capacitor, and
a fourth plug electrode in the fourth opening section.
